(19) United States
(12) Patent Application Publication
(10) Pub. No.: US 2026/0107712 A1
(43) Pub. Date: Apr. 16, 2026

(54) HYDROGEN REDUCTION OF SILICON NITRIDE PASSIVATION LAYER BY FORMATION AND TREATMENT OF PASSIVATION SUB-LAYERS

(71) Applicant: LAM RESEARCH CORPORATION, Fremont, CA (US)

(72) Inventors: Chongin PAK, Beaverton, OR (US); Chengzhu QI, Lake Oswego, OR (US)

(21) Appl. No.: 19/115,860

(22) PCT Filed: Sep. 20, 2023
(86) PCT No.: PCT/US2023/033258

§ 371 Date: Mar. 27, 2025

Related U.S. Application Data
(60) Provisional application No. 63/412,717, filed on Oct. 3, 2022.

(51) Int. Cl. H10P 14/694; H10P 14/60; H10W 74/10; H10W 74/43

(52) U.S. Cl. CPC H10P 14/69433; H10P 14/6532; H10W 74/137; H10W 74/43

(57) ABSTRACT

A method for developing a passivation film on a substrate with less than 10 atomic % of hydrogen includes providing the substrate within a processing station of a substrate processing system. A resultant passivation film is formed with less than 10 atomic % of hydrogen on the substrate by performing the following steps of depositing a passivation film sub-layer on the substrate, where the passivation film sub-layer lays on a semiconductor device layer or directly on a previously deposited passivation film sub-layer, and after depositing the passivation film sub-layer, performing a post plasma treatment to the passivation film sub-layer with at least one of nitrogen and argon to reduce hydrogen content within the passivation film sub-layer.

### CROSS-REFERENCE TO RELATED APPLICATIONS

This application is a PCT International Application and claims the benefit of U.S. Provisional Application No. 63/412,717, filed on Oct. 3, 2022. The entire disclosure of the above application is incorporated herein by reference.

### FIELD

The present disclosure relates to formation of passivation layers, and more particularly to reduction in hydrogen in a silicon nitride passivation layer.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform etching, deposition, and/or other treatment of substrates such as semiconductor wafers. As an example, a substrate may be arranged on an electrostatic chuck (ESC) in a substrate processing system. Multiple device layers may be formed on the substrate. Subsequent to forming the device layers, a passivation layer of silicon nitride (SIN) may be formed on the device layers using a plasma enhanced chemical vapor deposition (PECVD) process.

### SUMMARY

A method for developing a passivation film on a substrate with less than 10 atomic % of hydrogen is disclosed. The method includes providing the substrate within a processing station of a substrate processing system, and forming a resultant passivation film with less than 10 atomic % of hydrogen on the substrate by performing the following steps of: depositing a passivation film sub-layer on the substrate, where the passivation film sub-layer lays on a semiconductor device layer or directly on a previously deposited passivation film sub-layer; and after depositing the passivation film sub-layer, performing a post plasma treatment to the passivation film sub-layer with at least one of nitrogen and argon to reduce hydrogen content within the passivation film sub-layer.

In other features, the method includes: the substrate includes a stack of layers including the semiconductor device layer and other semiconductor device layers, the stack including at least one III-V type semiconductor material; and the step of depositing of the passivation film sub-layer includes depositing the passivation film sub-layer on the stack of layers.

In other features, a top layer of the stack of layers includes the at least one III-V type semiconductor material. In other features, the post plasma treatment of the passivation film sub-layer is performed to reduce the hydrogen content within the passivation film sub-layer to be less than or equal to 10.0 atomic %.

In other features, the post plasma treatment of the passivation film sub-layer is performed to reduce the hydrogen content within the passivation film sub-layer to be less than 10.0 atomic %. In other features, the post plasma treatment of the passivation film sub-layer is performed to reduce the hydrogen content within the passivation film sub-layer to be less than 7.5 atomic %.

In other features, the step of depositing of the passivation film sub-layer includes depositing the passivation film sub-layer to have a thickness less than 200 Å. In other features, the step of depositing of the passivation film sub-layer includes depositing the passivation film sub-layer to have a thickness less than 100 Å. In other features, the step of depositing of the passivation film sub-layer includes depositing the passivation film sub-layer to have a thickness less than 50 Å. In other features, the step of depositing of the passivation film sub-layer includes depositing the passivation film sub-layer to have a thickness of 20-40 Å.

In other features, the method further includes introducing the at least one of nitrogen and argon for more than 30 seconds. In other features, the method further includes introducing the at least one of nitrogen and argon for less than or equal to 60 seconds. In other features, the method further includes forming multiple passivation film sub-layers in the processing station on the substrate.

In other features, the method further includes forming passivation film sub-layers in processing stations on the substrate, such that each of the passivation film sub-layers is formed in one of the processing stations and not all of the passivation film sub-layers are formed in a same processing station.

In other features, a semiconductor device is disclosed and includes: a base layer; a stack of semiconductor device layers disposed on the base layer; and multiple passivation film sub-layers disposed on the stack of semiconductor device layers. A hydrogen content level collectively of the passivation film sub-layers is less than or equal to 10.0 atomic %.

In other features, the stack of semiconductor device layers includes at least one III-V type semiconductor material. In other features, a top layer of the stack of semiconductor device layers includes at least one III-V type semiconductor material.

In other features, the passivation film sub-layers are stacked as a single passivation layer. In other features, a WER of the single passivation layer is 6-10 Å/m. In other features, each of the passivation film sub-layers is an ammonia-free silicon nitride layer. In other features, the hydrogen content level of each of the passivation film sub-layers is less than or equal to 10.0 atomic %.

In other features, the hydrogen content level of each of the passivation film sub-layers is less than 10.0 atomic %. In other features, each of the passivation film sub-layers have a hydrogen content level of less than 7.5 atomic %.

In other features, a thickness of each of the passivation film sub-layers is less than 200 Å. In other features, a thickness of each of the passivation film sub-layers is less than 100 Å. In other features, a thickness of each of the passivation film sub-layers is less than 50 Å. In other features, a thickness of each of the passivation film sub-layers is 20-40 Å.

A method for passivating a semiconductor device within a substrate processing system is disclosed. The method includes: providing a substrate including the semiconductor device within a processing station of the substrate processing system; and iteratively performing a passivation process to form passivation film sub-layers on the semiconductor device. The passivation process includes: depositing a current passivation film sub-layer on a semiconductor device layer of the semiconductor device or a previously deposited one of the passivation film sub-layers; and post plasma treating the current passivation film sub-layer with at least one of nitrogen and argon to reduce hydrogen content within the current passivation film sub-layer.

In other features, the semiconductor device includes a stack of layers including the semiconductor device layer and other semiconductor device layers. The stack includes at least one III-V type semiconductor material. The passivation film sub-layers are deposited on the stack of layers. In other features, a top layer of the stack of layers includes the at least one III-V type semiconductor material.

In other features, the passivation film sub-layers are stacked to provide a single resultant passivation layer. In other features, the post plasma treating of the current passivation film sub-layer is performed to reduce the hydrogen content within the current passivation film sub-layer to be less than or equal to 10.0 atomic %.

In other features, the post plasma treating of the current passivation film sub-layer is performed to reduce the hydrogen content within the current passivation film sub-layer to be less than 10.0 atomic %. In other features, the post plasma treating of the current passivation film sub-layer is performed to reduce the hydrogen content within the current passivation film sub-layer to be less than 7.5 atomic %.

In other features, the current passivation film sub-layer is deposited to have a thickness less than 200 Å. In other features, the current passivation film sub-layer is deposited to have a thickness less than 100 Å. In other features, the current passivation film sub-layer is deposited to have a thickness less than 50 Å. In other features, the current passivation film sub-layer is deposited to have a thickness of 20-40 Å.

In other features, the method further includes introducing the at least one of nitrogen and argon for more than 30 seconds. In other features, the method further includes introducing the at least one of nitrogen and argon for less than or equal to 60 seconds.

In other features, the method further includes forming the passivation film sub-layers in the processing station. In other features, the method further includes forming the passivation film sub-layers in multiple processing stations, such that each of the passivation film sub-layers is formed in one of the processing stations and not all of the passivation film sub-layers are formed in a same processing station.

In other features, a semiconductor device is provided and includes: a base layer; a stack of semiconductor device layers disposed on the base layer; and passivation film sub-layers disposed on the stack of semiconductor device layers, where at least one of i) a hydrogen content level collectively of the passivation film sub-layers is less than or equal to 10.0 atomic %, and ii) each of the passivation film sub-layers has a hydrogen content level of less than or equal to 10.0 atomic %.

In other features, the stack of semiconductor device layers includes at least one III-V type semiconductor material. In other features, a top layer of the stack of semiconductor device layers includes at least one III-V type semiconductor material.

In other features, the passivation film sub-layers are stacked as a single passivation layer. In other features, a WER of the single passivation layer is 6-10 Å/m. In other features, each of the passivation film sub-layers is an ammonia-free silicon nitride layer.

In other features, the hydrogen content level of each of the passivation film sub-layers is less than or equal to 10.0 atomic %. In other features, the hydrogen content level of each of the passivation film sub-layers is less than 10.0 atomic %. In other features, each of the passivation film sub-layers have a hydrogen content level of less than 7.5 atomic %.

In other features, a thickness of each of the passivation film sub-layers is less than 200 Å. In other features, a thickness of each of the passivation film sub-layers is less than 100 Å. In other features, a thickness of each of the passivation film sub-layers is less than 50 Å. In other features, a thickness of each of the passivation film sub-layers is 20-40 Å.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system implementing a passivation method in accordance with an embodiment of the present disclosure;

FIG. 2 is a top cross-sectional view of the processing chamber of FIG. 1 including multiple processing stations utilized to deposit passivation film sub-layers and perform post plasma treatment in accordance with an embodiment of the present disclosure;

FIG. 3 is a cross-sectional side view of layers of a semiconductor device including semiconductor device layers and a resultant passivation layer formed by stacking and treating each of multiple passivation film sub-layers in accordance with the present disclosure;

FIG. 4 illustrates a passivation method for forming the resultant passivation layer of FIG. 3; and

FIG. 5 is a functional block diagram of an example of another substrate processing system implementing a passivation method in accordance with an embodiment of the present disclosure.

In the drawings, reference numbers may be reused to identify similar and/or identical elements.

### DETAILED DESCRIPTION

Devices such as radio frequency (RF) power devices, micro light emitting diodes, wide-band gap power devices, etc. include nitride material referred to as “III-V type” semiconductor materials. The III-V type semiconductor materials have a wurtzite structure and include gallium nitride (GaN), aluminum nitride (AlN), indium nitride (InN), and corresponding alloys. III-V type semiconductor-based devices have improved optical and electrical properties as compared to traditional silicon and silicon-carbide (SiC) based devices. Process integration of the III-V type semiconductor-based devices typically requires deposition of a relatively thin passivation layer directly in contact with the III-V type semiconductor-based devices. As an example, the passivation layer may be 20-300 nanometers (nm) thick depending on the purpose of passivation and the device structure. Increase of thickness (e.g., more than 300 nm) can cause degradation of device electrical properties, such as a reduction in a breakdown voltage. The purpose of the passivation layer is not only for providing protection from chemical-based degradation, but also for eliminating a potential for existence of a charge trapping source by introducing silicon (Si) or nickel (Ni) to the surface of the III-V type semiconductor-based device. This creates stringent requirements on the processing and physical properties of passivation film layers, such as requirements in hydrogen content, deposition temperatures, types of reactant species, and conformality. To satisfy some of these requirements, atomic layer deposition (ALD) may be implemented for passivation film layer formation. However, ALD is a slow process, which results in slow throughput and increased costs.

For applications requiring a passivation film layer, molecular hydrogen content of the passivation film layer is reduced to prevent hydrogen atoms from moving around and negatively affecting parts and operation of a semiconductor device, which can result in semiconductor device failures. Hence, in certain applications, it is desirable to have a very low hydrogen concentration in the passivation film layer.

The examples set forth herein include formation of resultant passivation film layers having low hydrogen concentration (e.g., less than 10 atomic % of hydrogen). Certain processes may be able to reduce the hydrogen concentration to 20 atomic %, but consistently creating a passivation film layer with less than 12 atomic % of hydrogen has been challenging. Atomic % of hydrogen represents the total number of hydrogen (H) atoms in the passivation layer over the total number of atoms in the passivation layer. In some examples, an iterative process to form multiple thin passivation film sub-layers is performed. Each thin passivation film sub-layer is then post plasma treated to remove hydrogen content. In some examples, the passivation film sub-layers are formed using NH₃-free silicon nitride deposition processes followed by a post treatment with nitrogen and/or argon. The post treatment with nitrogen and/or argon removes hydrogen from the passivation film sub-layers. Also, by forming multiple thin passivation film sub-layers, instead of depositing a single thick passivation film, the effectiveness of the post plasma treatment is increased to further minimize the overall hydrogen content.

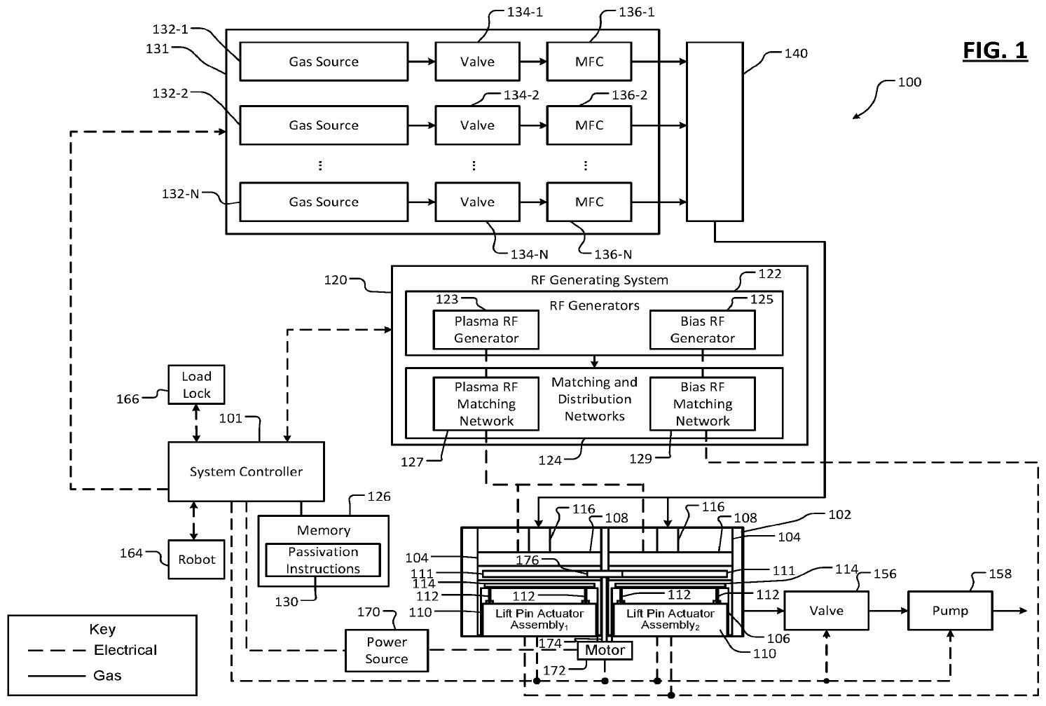

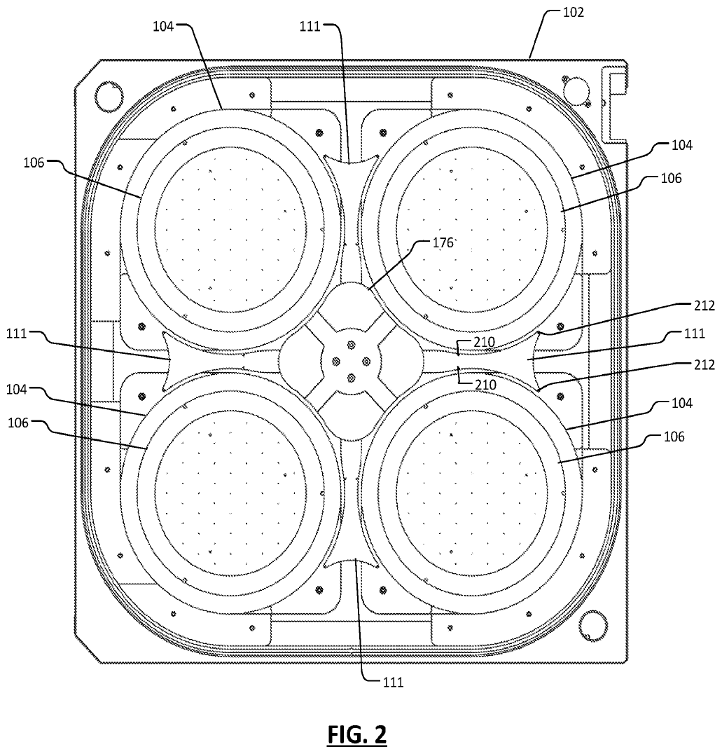

FIG. 1 shows an example substrate processing system (or tool) 100 including a system controller 101 implementing a passivation method to form distinct passivation film sub-layers and perform post plasma treatment of the passivation film sub-layers, as further described below. The substrate processing system 100 includes a processing chamber 102 having multiple processing stations 104, two processing stations are shown in FIG. 1, however, the processing chamber 102 may have four processing stations as shown in FIG. 2.

In one embodiment, each of the processing stations 104 may be used to complete a resultant passivation layer on a respective substrate including depositing multiple passivation film sub-layers on the respective substrate. Each substate may include multiple semiconductor devices on which the passivation film sub-layers are formed. Post plasma treatment is performed on each of the passivation film sub-layers. As an example, 20 passivation film sub-layers may be deposited on a substrate within a processing station and each passivation film sub-layer is post plasma treated prior to depositing a next passivation film sub-layer and/or completion of resultant passivation layer formation. This is also called non-sequential operation mode for film formation.

In another embodiment, each of the processing stations 104 deposits one or more passivation film sub-layers of a resultant passivation layer on each of multiple substrates. Each substate may include multiple semiconductor devices on which the passivation film sub-layers are formed. In this example embodiment, each substrate is moved from processing station to processing station to form the passivation film sub-layers. In one embodiment, a single passivation film sub-layer is formed in a first processing station and then the corresponding substrate is moved to a next processing station to form a next passivation film sub-layer. This continues until all passivation film sub-layers are formed on that substrate. Each substrate is moved between adjacent processing stations subsequent to depositing a passivation film sub-layer and performing post plasma treatment on that passivation film sub-layer. This is also called sequential operation mode for film formation.

As an example, 20 passivation film sub-layers of a resultant passivation layer may be formed on each of 4 substrates, where 5 passivation film sub-layers are formed in each of four processing stations for each of the 4 substrates. Post plasma treatment is performed on each of the passivation film sub-layers. Post plasma treatment of each passivation film sub-layer is performed in the processing station where that passivation film sub-layer is deposited. The sequential operation mode improves passivation film sub-layer and resultant passivation layer uniformity from substrate-to-substrate.

Each of the processing stations 104 includes respective substrate supports (e.g., substrate supports 106), such as electrostatic chucks, and showerheads (e.g., showerheads 108). The substrate supports include respective lift pin actuator assemblies (e.g., lift pin actuator assemblies 110). The lift pin actuator assemblies include lift pins (e.g., lift pins 112) that are actuated to lift substrates (e.g., substrates 114) on and off of the substrate supports and substrate transfer paddles 111.

Each of the processing stations 104 includes upper and lower electrodes. The showerheads may be implemented as or include the upper electrodes. The substrate supports may be implemented as or include the lower electrodes. The upper and lower electrodes may be implemented as radio frequency (RF) electrodes, bias electrodes, clamping electrodes and/or heating electrodes. For example, the upper electrodes may be implemented as the showerheads, which introduce and distributes gases in the processing stations. The showerheads may include stem portions 116 including ends connected to top surfaces of the processing chamber 102. The showerheads are generally cylindrical and extend radially outward from opposite ends of the stem portions 116 at a location that is spaced from the top surface of the processing chamber. Substrate-facing surfaces of the showerheads include holes through which process or purge gas flows. Alternately, the showerheads may include a conducting plate and the gases may be introduced in another manner.

An RF generating system 120 generates and outputs RF voltages to the upper electrodes and the lower electrodes. For each of the processing stations, one of the upper electrodes and the lower electrodes may be DC grounded, AC grounded or at a floating potential. For example, the RF generating system 120 may be controlled by the system controller 101 and include one or more RF generators 122 (e.g., a capacitive coupled plasma RF power generator, a bias power generator, and/or other RF power generator) that generate RF voltages, which are fed by one or more matching and distribution networks 124 to the upper electrodes and/or the lower electrodes. The system controller 101 sets and adjusts frequencies of RF signals output from the RF generators 123, 125. The frequencies may be adjusted to adjust power distribution within and across the substrate supports. The system controller 101 may be connected to and/or include memory 126, which may store passivation instructions 130 for implementing the passivation methods disclosed herein.

As an example, a first RF generator 123, a second RF generator 125, a first RF matching network 127 and a second RF matching network 129 are shown. The first RF generator 123 and the first RF matching network 127 may provide a RF voltage or may simply connect the showerheads to a ground reference. The second RF generator 125 and the second RF matching network 129 may each or collectively be referred to as a power source and provide a RF/bias voltage to the substrate supports. In one embodiment, the first RF generator 123 and the first RF matching network 127 provides power that ionizes gas and drives plasma. In another embodiment, the second RF generator 125 and the second RF matching network 129 provides power that ionizes gas and drives plasma. One of the RF generators 123, 125 may be a high-power RF generator producing, for example 6-10 kilo-watts (kW) of power or more.

A gas delivery system 131 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. During passivation film sub-layer formation silane and nitrogen may be supplied from the gas sources 132 to the processing chamber 102. During post plasma treatment of passivation film sub-layers, nitrogen and/or argon may be supplied from one or more of the gas sources 132 to the processing chamber 102. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example, the output of the manifold 140 is fed to the showerheads.

A valve 156 and pump 158 may be used to evacuate reactants from the processing chamber 102. The system controller 101 may control components of the substrate processing system 100 including controlling supplied RF power levels, pressures and flow rates of supplied gases, RF matching, etc. The system controller 101 controls states of the valve 156 and the pump 158. A robot 164 may be used to deliver substrates into and remove substrates from the processing stations 104. For example, the robot 164 may transfer substrates between the substrate supports 106 and a load lock 166. The robot 164 may be controlled by the system controller 101. The system controller 101 may control operation of the load lock 166. The valves, gas and/or coolant pumps, power sources, RF generators, etc. may be referred to as actuators.

The substrate processing system 100 further includes a power source 170 that may supply power to the system controller 101, the lift pin actuator assemblies 110 and a motor 172. The motor 172 rotates the spindle 174. The power source 170 may be controlled by the system controller 101. The system controller 101 may control supply of power from the power source 170 to the motor 172 and/or to the RF generating system 120.

The lift pin actuator assemblies 110 raise and lower the lift pins 112. The lift pins actuator assemblies 110 may include electrical and/or pneumatic actuators for adjusting positions of the lift pins 112. The motor 172 rotates a spindle 174, which is connected to a hub 176. The hub 176 is connected to hub portions of the substrate transfer paddles 111. The hub portions may be held by the hub 176 using various techniques. In one embodiment, the hub portions are clamped in the hub 176 and thus held by the hub 176, In another embodiment, the hub portions are inserted into and supported (or held) by the hub 176. The substrate transfer paddles 111 may extend laterally and/or horizontally from the hub 176. Top and/or bottom planar surfaces of the substrate transfer paddles 111 may be parallel to top and/or bottom planar surfaces of the substrate supports 106.

During operation, the substrate transfer paddles 111 are rotated to position the substrates 114 over the substrate supports 106. The lift pins 112 are raised to lift the substrates 114 off the substrate transfer paddles 111 and the substrate transfer paddles 111 are rotated out of the way to stowed positions. The lift pins 112 are then lowered to set the substrates 114 on the substrate supports 106. One or more processing operations (e.g., etch, deposition, or clean operation) are then performed on the substrates 114. Subsequently, the lift pins 112 are raised to lift the substrates off of the substrate supports 106 and the substrate transfer paddles 111 are rotated to be between the substrate supports 106 and the substrates 114. The lift pins 112 are then lowered to set the substrates 114 back on the substrate transfer paddles 111. This process may be repeated and the substrates may be moved from processing station to processing station in this manner. Each processing station may perform a different set of processing operations.

The lift pins 112 may also be used to allow delivery and removal of the substrates 114 from the processing chamber 102 using a robot arm of the robot 164. Upper ends of the lift pins 112 may be located flush with or below upper surfaces of the substrate supports 106 when stowed. During substrate delivery, removal and/or transfer, the lift pins are raised relative to the upper surfaces of the substrate supports 106 to lift the substrates 114 and provide clearance between the substrates 114 and the substrate supports 106. The clearance between the substrates 114 and the substrate supports 106 allows (i) an end effector of the robot arm to be inserted or removed, and (ii) the substrate transfer paddles to be moved between the substrates 114 and the substrate supports 106.

FIG. 2 shows the processing chamber 102 including the processing stations 104. The processing stations 104 are utilized to deposit passivation film sub-layers and perform post plasma treatment of the passivation film sub-layers. The processing chamber 102 is shown with the substrate transfer paddles 111 in a stowed state but may be rotated over substrate supports 106 to a deployed state.

The substrate transfer paddles 111 are held by and extend from the hub 176. In the stowed state, the substrate transfer paddles 111 are disposed between the processing stations 104. When deployed, the substrate transfer paddles 111 are disposed in locations between the stowed positions. Rotation of the hub 176 rotates the substrate transfer paddles 111 from current processing stations to stowed positions and then from the stowed positions to next processing stations in a clockwise or counterclockwise direction.

As an example, the substrate transfer paddles 111 are shown including support pins. The supports pins on one of the substrate transfer paddles 111 are designated 210 and 212. The support pins on the other ones of the substrate transfer paddles 111 may be configured similarly as the support pins 210, 212. The support pins 210 are located radially inward of the support pins 212. For each of the substrate transfer paddles 202, the support pins 210 are located along the substrate transfer paddle between the hub 176 and the support pins 212.

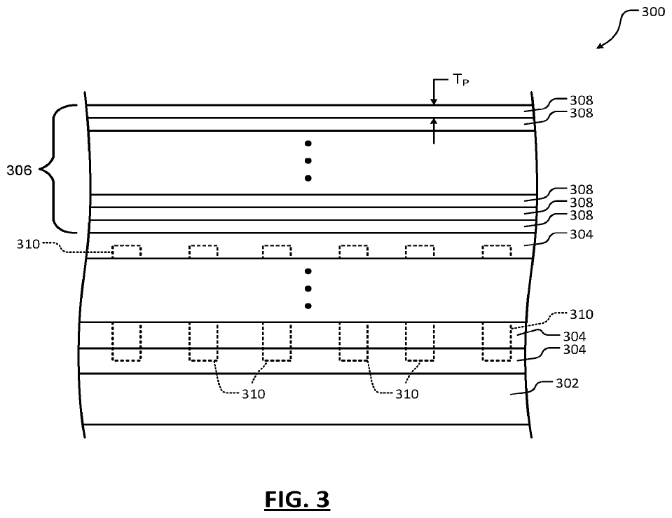

FIG. 3 shows a substrate 300 that includes a base layer 302, semiconductor device layers 304, and a resultant passivation layer 306. The resultant passivation layer 306 includes a stack of passivation film sub-layers 308, which each have been post plasma treated. The passivation film sub-layers 308 may be referred to as post plasma treated passivation layers. The semiconductor device layers 304 may include semiconductor devices, such as one or more micro-light emitting diodes (LEDs), one or more wide band gap power devices, one or more memory devices, or other known semiconductor devices. The semiconductor devices are represented as dashed boxes 310 and may each be included in some or all of the semiconductor device layers 304. In some instances, the semiconductor device layers 304 include multiple semiconductor devices. The semiconductor device layers 304 may include, for example, metal layers, dielectric layers, intermediate coupling layers, P, I and/or N type doped layers, etc. The semiconductor device layers 304 may include III-V type semiconductor materials such as GaN, AlN, InN and/or other nitride materials and/or corresponding alloys. The semiconductor device layers 304 may include semiconductor devices requiring formation thereon of a passivation layer with a low atomic % of hydrogen. A bottom most one of the passivation film sub-layers 308 may be in contact with one or more of the semiconductor devices 310 or may be separated from the semiconductor devices by one or more other layers.

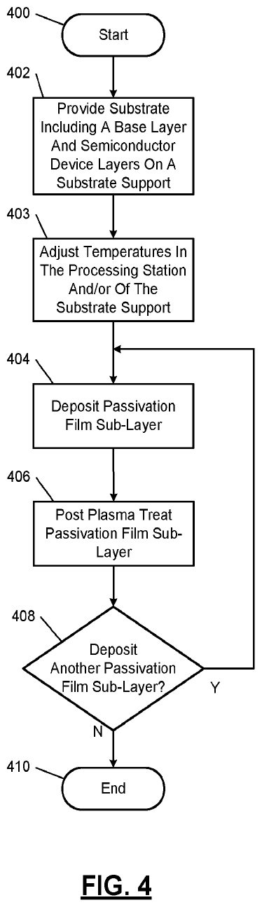

The passivation film sub-layers 308 may each be formed of SIN and/or ultraviolet (UV) light transparent SIN (UV-SIN). In an embodiment, the passivation film sub-layers 308 are formed without use of ammonia (NH₃), referred to as the NH₃-free process. In an embodiment, silane (SiH₄) and nitrogen are introduced to form each of the passivation film sub-layers 308. This is done to provide NH₃-free silicon nitride film sub-layers. As an example, if the passivation film sub-layers 308 are formed by introducing SiH₄ and NH₃, the resulting passivation film sub-layer may have a hydrogen content of 20 to 30 atomic %. The introduction of NH₃ increases the hydrogen content level of a passivation layer. By using a NH₃-free process the hydrogen content may reduce to 11-15 atomic % in some instances. Each of passivation film sub-layers 308 have a set thickness and/or thicknesses within a set range, one example thickness TP is shown in FIG. 3. The passivation film sub-layers 308 may have the same thickness or may have different thicknesses. In one embodiment, the passivation film sub-layers 308 have the same thickness. Example thicknesses and ranges are disclosed below with respect to the method of FIG. 4.

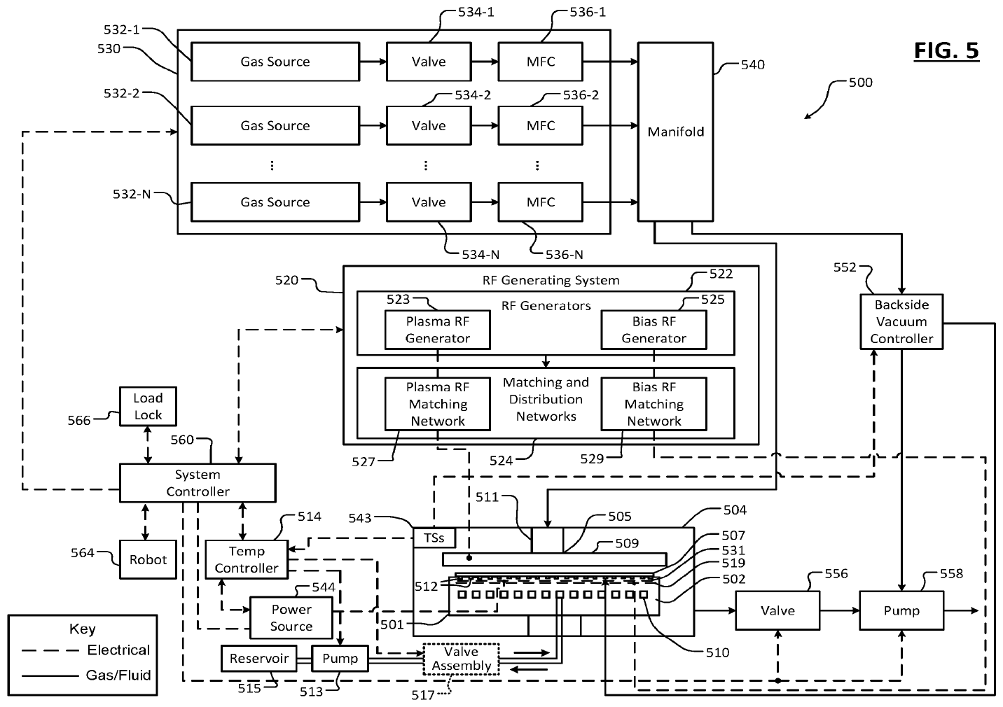

FIG. 4 shows a method of forming the resultant passivation layer 306 of FIG. 3, which may be implemented using the substrate processing system 100 of FIG. 1 or the substrate processing system 500 of FIG. 5. Although the following operations are described with respect to a single processing station operating in the non-sequential operation mode, the operations may be modified for sequential operation mode. The following operations are primarily described with respect to the substrate processing system of FIG. 1 but are also applicable to the substrate processing system of FIG. 5. As an example, the operations may be implemented by the system controller 101 executing the passivation layer instructions 130.

The method may begin at 400. At 402, a substrate (or semiconductor wafer) may be introduced into the processing station if not already in the processing station and placed on a substrate support. The substrate may include a base layer and one or more semiconductor device layers, such as the base layer 302 and the semiconductor device layers 304, which include semiconductor devices 310.

At 403, the system controller 101 may adjust the temperature in the processing stations and/or of the substrate support to adjust the temperature of the substrate to be within a predetermined range. As an example, the temperature of the substrate may be adjusted to be 400-450° C. In an embodiment, the temperature of the substrate is adjusted to be 425° C. FIG. 5 shows an example including a temperature control system 514 that may be used to adjust the stated temperatures. A similar temperature control system may be implemented for each processing station of the example of FIG. 1.

The following operations 404 and 406 are performed in at least one iteration to develop a low hydrogen concentration film. In some embodiments, operations 404 and 406 are performed iteratively until a desired resultant layer thickness is met or until a predetermined number of sub-layers are formed. Each iteration may be referred to as a passivation sub-layer cycle. A SIN and/or UV-SIN passivation film sub-layer is formed during each cycle with minimal hydrogen content. As an example, more than 20 cycles may be performed to form more than 20 passivation film sub-layers. In one embodiment, 20-40 passivation film sub-layers are formed.

At 404, a deposition step is performed including introducing SiH₄ and nitrogen into the processing station to deposit a passivation film sub-layer on the top surface(s) of the stack of semiconductor device layers or on a top surface of the last deposited passivation film sub-layer. The deposition step in some instances is a PECVD process. In some embodiments, the deposition step may utilize a dual radio frequency (RF) process including providing dual frequencies, such as 13.56 MHz and 400 kHz. Other radio frequencies may be used. Dual frequencies may be used to tune passivation layer film stress to a target level. Passivation layers can require a mild compressive stress for better adhesion to a semiconductor device layer. Use of dual frequencies provides a larger process space to dial in the film stress. The deposition step however in some instances may utilize a single radio frequency.

In some examples, the passivation film sub-layer is formed using a NH₃-free silicon nitride PECVD deposition process. In one embodiment, operation 404 is performed for 1-2 seconds. In another embodiment, the PECVD time is 1 second. In another embodiment, the PECVD time is less than 1 second but more than 0.5 second. The passivation film sub-layer is thin, for example, less than 200 Å thick. In one embodiment, the passivation film sub-layer is less than 100 Å thick. In another embodiment, the thickness is less than 50 Å thick Å. In another embodiment, the thickness is 20-30 Å thick. The thickness of the passivation film sub-layer is partially dependent on the time of the deposition process/step, where a longer deposition time may correspond to a thicker sub-layer. Generally, the subsequently performed post plasma treatment can remove H atoms more effectively when the passivation film sub-layer is thinner.

At 406, the passivation film sublayer is post plasma treated using at least one of nitrogen and argon. During post plasma treatment, nitrogen and/or argon are introduced into the chamber 102. The nitrogen and/or argon may be injected into the processing chamber in a range of 8000-13000 standard cubic centimeters per minute (sccm) and the pressure within the processing chamber may be 4-8.5 torr (T). In one embodiment, nitrogen is introduced without argon. In another embodiment argon is introduced without nitrogen. In yet another embodiment, nitrogen and argon are both introduced. Post plasma treatment helps to release hydrogen content in the film sublayer, resulting in lower film hydrogen concentration levels. The post plasma treatment reduces hydrogen by breaking silicon-hydrogen (SiH) bonds and releasing hydrogen out of the film. In some embodiments, the post plasma treatment includes exposing the passivation film sub-layer to nitrogen and/or argon. As an example, the exposure may be for 10-60 seconds in duration. In one embodiment, the exposure is at least 30 seconds. In another embodiment, the exposure is less than or equal to 60 seconds. In another embodiment, the exposure is less than or equal to 40 seconds. In another embodiment, the exposure is 60 seconds. Effectiveness of post plasma treatment in removing hydrogen may be greatest when 30-60 seconds in duration. Effectiveness of removing hydrogen may decrease after 40 seconds of exposure. The effectiveness refers to the amount and rate at which hydrogen is removed. In some instances, from 40-60 seconds the amount of hydrogen removal is reduced compared to the hydrogen removal effectiveness from 10-40 seconds. In some instances, hydrogen removal effectiveness reduced significantly after 60 seconds such that the benefit of post plasma treatment is negligible.

In one embodiment, the post plasma treatment is performed for a length of time to reduce the hydrogen atomic % to less than 10 atomic %. In another embodiment, the post plasma treatment is performed for a length of time to reduce the hydrogen atomic % to be between 7-10 atomic %. In another embodiment, the post plasma treatment is performed for a length of time to reduce the hydrogen atomic % to be between 7-8 atomic %. In another embodiment, the hydrogen atomic % is less than 7.5%.

In one embodiment, RF power is not provided during post plasma treatment. In another embodiment, RF power is supplied. The post plasma treatment may be a dual frequency process and include the supply of RF power at the same frequencies or at different frequencies than that introduced during the deposition process used to form the passivation film sub-layer being treated.

At 408, the system controller determines whether another passivation film sublayer is to be formed. If yes, operations 404 and 406 are performed again, otherwise the method may end 410.

By repeating deposition-plasma treatment cycling—operations 404 and 406, in-film H content of the resultant passivation layer is reduced. As an example, the in-film H content may be reduced from as much as 20 atomic % to being less than 8 atomic %, for example, 7.3 atomic %. Quantitative analysis of hydrogen content to determine the atomic % may be accomplished, for example, using hydrogen forward scattering spectroscopy (HFSS). This may be performed after depositing a predetermined number of passivation film sub-layers and/or after formation of the resultant passivation layer.

HFSS is an ion scattering technique that is used to quantitatively determine the vertical distribution of hydrogen in thin films. During a HFSS process, He₂₊ ions hit the sample surface at a glancing angle, knocking hydrogen atoms out of the sample, which can then be analyzed using a solid-state detector. The ability to measure the composition and vertical distribution of hydrogen content within a thin film may be performed to gain an understanding of the physical and/or electrical properties of the thin film. The higher the hydrogen concentration level, the higher the impact on a film's physical and/or electrical properties. Other techniques, such as auger electron spectroscopy (AES), energy dispersive X-ray spectroscopy (EDS) and X-ray photoelectron spectroscopy (XPS) cannot detect hydrogen concentration levels; and while a secondary ion mask spectrometer (SIMS) can measure hydrogen, quantification of the hydrogen by SIMS can be difficult and requires standards. HFSS provides a non-destructive method for measuring hydrogen content. A whole wafer is able to be analyzed using HFSS. Conductors and insulators may be analyzed. HFSS has a depth resolution of 300 Å.

As a comparative example using HFSS, a NH3-free SiN passivation layer formed using a dual RF PECVD process at a temperature of 400° C. without post plasma treatment may have a 17 atomic % of hydrogen content. A NH3-free SiN passivation layer formed using a dual RF PECVD process at a temperature of 425° C. without post plasma treatment may have a 11 atomic % of hydrogen content. A NH3-free SiN passivation layer formed using a dual RF PECVD process at a temperature of 425° C. with post plasma treatment may have a 8 atomic % of hydrogen content. Until utilizing the processes disclosed above, it has been a challenge to develop a SIN passivation layer with less than 10 atomic % of hydrogen.

Another technique that may be used to indirectly estimate the hydrogen content is to determine a wet etch rate (WER) of, for example, the resultant passivation layer. The lower the hydrogen content (or atomic % of hydrogen), the slower the WER. In some embodiments, the resultant passivation layer developed using the process described above has a low WER (e.g., using nitrogen in post plasma treatment with dual RF power at 425° C.), such as 6.2-6.4 Angstroms per minute (Å/m) with 100:1 diluted hydrofluoric acid (dHF) dip for 5 m. There is an inverse relationship between WER and a duration of post plasma treatment. A minimum change in the WER exists when the duration of post plasma treatment is increased from 40-60 seconds. This indicates that there is negligible benefit achieved with post plasma treatment longer than 60 seconds.

As another comparative example, a NH3-free SiN passivation layer formed using a dual RF PECVD process without post plasma treatment may have a WER of 17 angstroms per minute (A/m). A NH3-free SIN passivation layer formed using a dual RF PECVD process and a post plasma treatment without RF power may have a WER of 12-18 Å/m. A NH3-free SIN passivation layer formed using a dual RF PECVD process with a dual RF post plasma treatment including introduction of argon (Ar) may have a WER of 10-15 Å/m. A NH3-free SIN passivation layer formed using a dual RF PECVD process with a dual RF post plasma treatment including introduction of nitrogen (N₂) may have a WER of 6-10 Å/m. As the thickness of the passivation film sub-layer decreases, the WER decreases. A low WER is an indicator of a low level of hydrogen content.

FIG. 5 shows an example substrate processing system 500 including a substrate support 501, shown as an electrostatic chuck. In the example shown, the substrate support 501 includes a body 502. The body 502 may be formed of different materials and/or different ceramic compositions. The body 502 may include, for example, aluminum alloy, aluminum nitride (AlN₃), aluminum oxide (Al₂O3), and/or aluminum oxynitride (AlON).

The substrate processing system 500 includes a processing chamber 504. The substrate support 501 is enclosed within the processing chamber 504. The processing chamber 504 also encloses other components, such as an upper electrode 505, and contains RF plasma. During operation, a substrate 507 is arranged on and electrostatically clamped to the substrate support 501. For example, the upper electrode 505 may include a showerhead 509 that introduces and distributes gases. The showerhead 509 may include a stem portion 511 including one end connected to a top surface of the processing chamber 504. The showerhead 509 is generally cylindrical and extends radially outward from an opposite end of the stem portion 511 at a location that is spaced from the top surface of the processing chamber 504. A substrate-facing surface of the showerhead 509 includes holes through which process or purge gas flows. Alternately, the upper electrode 505 may include a conducting plate and the gases may be introduced in another manner. In an embodiment, the substrate support 501 may include one or more gas channels 512 for flowing backside gas to a backside of the substrate 507.

The substrate support 501 may include one or more coolant channels 510, which receives a coolant from a pump 513. A temperature controller 514 may control operation of the pump 513 to control flow and temperature of coolant to and from the coolant channels 510. The pump 513 may circulate coolant between a reservoir 515 and the coolant channels 510. Although a single pump 513 is shown, two or more pumps may be included. A valve assembly 517 may be disposed between the pump 513 and the coolant channels 510 and be controlled by the temperature controller 514. Supply and return lines may be connected (i) between the one or more pumps and the coolant channels 510, and/or (ii) between the valve assembly 517 and the coolant channels 510.

An RF generating system 520 generates and outputs RF voltages to the upper electrode 505 and one or more lower electrodes 519 in the substrate support 501. One of the upper electrode 505 and the substrate support 501 may be DC grounded, AC grounded or at a floating potential. For example, the RF generating system 520 may include one or more RF generators 522 (e.g., a capacitive coupled plasma RF power generator, a bias RF power generator, and/or other RF power generator) that generate RF voltages, which are fed by one or more matching and distribution networks 524 to the upper electrode 505 and/or the substrate support 501. An electrode that receives an RF signal, an RF voltage and/or RF power is referred to as a RF electrode. As an example, a plasma RF generator 523, a bias RF generator 525, a plasma RF matching network 527 and a bias RF matching network 529 are shown. The plasma RF generator 523 may be a high-power RF generator producing, for example, 6-10 kilo-watts (kW) of power or more. The bias RF matching network supplies power to RF electrodes, such as RF electrodes 519.

A gas delivery system 530 includes one or more gas sources 532-1, 532-2, . . . , and 532-N (collectively gas sources 532), where N is an integer greater than zero. The gas sources 532 supply one or more precursors and gas mixtures thereof. The gases sources 532 may supply silane, nitrogen and/or argon as described above for forming and post plasma treating passivation film sub-layers. The gas sources 532 may also supply etch gas, carrier gas and/or purge gas. Vaporized precursor may also be used. The gas sources 532 are connected by valves 534-1, 534-2, . . . , and 534-N (collectively valves 534) and mass flow controllers 536-1, 536-2, . . . , and 536-N (collectively mass flow controllers 536) to a manifold 540. An output of the manifold 540 is fed to the processing chamber 504. For example, the output of the manifold 540 is fed to the showerhead 509.

Although shown separately from a system controller 560, the temperature controller 514 may be implemented as part of the system controller 560. The substrate support 501 may include multiple temperature controlled zones, where each of the zones includes a temperature sensor and a set of microchannels. The temperature controller 514 may monitor temperatures as indicated by the temperature sensors and adjust flow rate and/or temperature of coolant circulating through the one or more sets of microchannels to adjust the temperatures to target temperatures.

The substrate processing system 500 may also include a power source 544 that provides power, including a high voltage, to clamping electrodes 531 to electrostatically clamp the substrate 507 to the substrate support 501. Clamping electrodes receive power to electrostatically clamp down the substrate 507 to the substrate support 501 and may receive RF signals, RF voltages and/or RF power. The power source 544 may be controlled by the system controller 560.

The substrate processing system 500 may further include a backside vacuum controller 552. The backside vacuum controller 552 may receive gas from the manifold 540 and supply the gas to the channels 512 and/or to a pump 558. This improves transfer of thermal energy between the substrate support 501 and the substrate 507. The backside gas may also be provided to improve substrate peripheral edge purging and vacuum tracking of a location of the substrate. The channels 512 may be fed by one or more injection ports. In one embodiment, multiple injection ports are included for improved cooling. As an example, the backside gas may include helium.

The temperature controller 514 may control operation of the pump 513 and/or other coolant circulating pumps and/or the valve assembly 517 based on detected parameters from temperature sensors 543 within the processing chamber 504. The backside vacuum controller 552 controls flow rate of backside gas (e.g., helium) to the channels 512 for cooling the substrate 507 by controlling flow from one or more of the gas sources 532 to the channels 512. The backside vacuum controller 552 controls pressure and flow rates of gas supplied to channels 512 based on detected parameters from the temperature sensors 543. In one embodiment, the temperature controller 514 and the backside vacuum controller 552 are implemented as a combined single controller.

The temperature sensors 543 may include resistive temperature devices, thermocouples, digital temperature sensors, and/or other suitable temperature sensors. One or more of the temperatures sensors 543 may be disposed in and be used to detect temperatures of the substrate support 501. During a deposition process, the substrate 507 may be heated in presence of high-power plasma. Flow of gas through the channels 512 may reduce temperatures of the substrate 507.

A valve 556 and the pump 558 may be used to evacuate reactants from the processing chamber 504. The system controller 560 may control components of the substrate processing system 500 including controlling supplied RF power levels, pressures and flow rates of supplied gases, RF matching, etc. The system controller 560 controls states of the valve 556 and the pump 558. The system controller 560 may be configured similarly and/or operate similarly as the system controller 101 of FIG. 1 and vice versa. A robot 564 may be used to deliver substrates onto, and remove substrates from, the substrate support 501. For example, the robot 564 may transfer substrates between the substrate support 501 and a load lock 566. The robot 564 may be controlled by the system controller 560. The system controller 560 may control operation of the load lock 566.

The valves, gas pumps, power sources, RF generators, etc. referred to herein may be referred to as actuators. The coolant channels, gas channels, etc. referred to herein may be referred to as temperature adjusting elements. Other temperature control elements may also be included in the substrate support, such as heating elements. In the example shown, the electrodes 519, 531 are disposed in an uppermost one of the layers of the substrate support 501. The coolant channels 510 are disposed in another one or more of the layers.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,”, “on”, “above,” “below,” and “disposed.” Unless explicitly described as being “direct” or “directly,” when a relationship between first and second elements is described in the above disclosure, that relationship can be a direct relationship where no other intervening elements are present between the first and second elements but can also be an indirect relationship where one or more intervening elements are present (either spatially or functionally) between the first and second elements. As an example, a first layer disposed on a second layer indicates that the first layer is above and over a portion of the second layer. The first layer may be in direct contact with the second layer or may be separated from the second layer by one or more intervening (or intermediate) layers. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for developing a passivation film on a substrate with less than 10 atomic % of hydrogen, the method comprising:
providing the substrate within a processing station of a substrate processing system; and
forming a resultant passivation film with less than 10 atomic % of hydrogen on the substrate by performing the following steps of
depositing a passivation film sub-layer on the substrate, wherein the passivation film sub-layer lays on a semiconductor device layer or directly on a previously deposited passivation film sub-layer, and
after depositing the passivation film sub-layer, performing a post plasma treatment to the passivation film sub-layer with at least one of nitrogen and argon to reduce hydrogen content within the passivation film sub-layer.

2. The method of claim 1, wherein:
the substrate comprises a stack of layers including the semiconductor device layer and other semiconductor device layers, the stack including at least one III-V type semiconductor material; and
the step of depositing of the passivation film sub-layer comprises depositing the passivation film sub-layer on the stack of layers.

3. The method of claim 2, wherein a top layer of the stack of layers includes the at least one III-V type semiconductor material.

4. The method of claim 1, wherein the post plasma treatment of the passivation film sub-layer is performed to reduce the hydrogen content within the passivation film sub-layer to be less than or equal to 10.0 atomic %.

5. The method of claim 1, wherein the post plasma treatment of the passivation film sub-layer is performed to reduce the hydrogen content within the passivation film sub-layer to be less than 10.0 atomic %.

6. The method of claim 1, wherein the post plasma treatment of the passivation film sub-layer is performed to reduce the hydrogen content within the passivation film sub-layer to be less than 7.5 atomic %.

7. The method of claim 1, wherein the step of depositing of the passivation film sub-layer comprises depositing the passivation film sub-layer to have a thickness less than 200 Å.

8. The method of claim 1, wherein the step of depositing of the passivation film sub-layer comprises depositing the passivation film sub-layer to have a thickness less than 100 Å.

9. The method of claim 1, wherein the step of depositing of the passivation film sub-layer comprises depositing the passivation film sub-layer to have a thickness less than 50 Å.

10. The method of claim 1, wherein the step of depositing of the passivation film sub-layer comprises depositing the passivation film sub-layer to have a thickness of 20-40 Å.

11. The method of claim 1, further comprising introducing the at least one of nitrogen and argon for more than 30 seconds.

12. The method of claim 1, further comprising introducing the at least one of nitrogen and argon for less than or equal to 60 seconds.

13. The method of claim 1, further comprising forming a plurality of passivation film sub-layers in the processing station on the substrate.

14. The method of claim 1, further comprising forming a plurality of passivation film sub-layers in a plurality of processing stations on the substrate, such that each of the plurality of passivation film sub-layers is formed in one of the plurality of processing stations and not all of the plurality of passivation film sub-layers are formed in a same processing station.

15. A semiconductor device comprising:
a base layer;
a stack of semiconductor device layers disposed on the base layer; and
a plurality of passivation film sub-layers disposed on the stack of semiconductor device layers, wherein a hydrogen content level collectively of the plurality of passivation film sub-layers is less than or equal to 10.0 atomic %.

16. The semiconductor device of claim 15, wherein the stack of semiconductor device layers includes at least one III-V type semiconductor material.

17. The semiconductor device of claim 15, wherein a top layer of the stack of semiconductor device layers includes at least one III-V type semiconductor material.

18. The semiconductor device of claim 15, wherein the plurality of passivation film sub-layers are stacked as a single passivation layer.

19. The semiconductor device of claim 18, wherein a WER of the single passivation layer is 6-10 Å/m.

20. The semiconductor device of claim 15, wherein each of the plurality of passivation film sub-layers is an ammonia-free silicon nitride layer.

21. The semiconductor device of claim 15, wherein the hydrogen content level of each of the plurality of passivation film sub-layers is less than or equal to 10.0 atomic %.

22. The semiconductor device of claim 15, wherein the hydrogen content level of each of the plurality of passivation film sub-layers is less than 10.0 atomic %.

23. The semiconductor device of claim 15, wherein each of the plurality of passivation film sub-layers have a hydrogen content level of less than 7.5 atomic %.

24. The semiconductor device of claim 15, wherein a thickness of each of the plurality of passivation film sub-layers is less than 200 Å.

25. The semiconductor device of claim 15, wherein a thickness of each of the plurality of passivation film sub-layers is less than 100 Å.

26. The semiconductor device of claim 15, wherein a thickness of each of the plurality of passivation film sub-layers is less than 50 Å.

27. The semiconductor device of claim 15, wherein a thickness of each of the plurality of passivation film sub-layers is 20-40 Å.
